(19) United States
(12) Patent Application Publication
(10) Pub. No.: US 2025/0014911 A1
(43) Pub. Date: Jan. 9, 2025

(54) PAD-IN-A-BOTTLE AND SINGLE PLATEN CHEMICAL MECHANICAL-PLANARIZATION FOR BACK-END APPLICATIONS

(71) Applicant: VERSUM MATERIALS US, LLC, TEMPE, AZ (US)

(72) Inventors: XIAOBO SHI, CHANDLER, AZ (US); JOHN G LANGAN, TEMPE, AZ (US); MARK LEONARD O'NEILL, QUEEN CREEK, AZ (US); ROBERT VACASSY, PHOENIX, AZ (US); JAMES A. SCHLUETER, PHOENIX, AZ (US); ARA PHILIPOSSIAN, TUCSON, AZ (US); YASA SAMPURNO, TUCSON, AZ (US)

(21) Appl. No.: 18/708,723

(22) PCT Filed: Nov. 4, 2022
(86) PCT No.: PCT/US2022/079271

§ 371 Date: May 9, 2024

Related U.S. Application Data
(60) Provisional application No. 63/278,049, filed on Nov. 10, 2021.

(51) Int. Cl. H01L 21/321; B24B 37/24; C09G 1/02; H01L 21/3105

(52) U.S. Cl. CPC H01L 21/3212; B24B 37/24; C09G 1/02; H01L 21/31053

(57) ABSTRACT

A single platen Chemical Mechanical Planarization (CMP) process using a novel pad-in-a-bottle (PIB) technology and PIB type CMP slurries for back-end CMP application is described to replace multiple (such as three) platens Chemical Mechanical Planarization (CMP) process for back-end CMP applications. The single platen with a single polishing pad is used for the whole back-end CMP process comprising metal bulk, metal soft landing, and metal barrier CMP.

### RELATED APPLICATIONS

This application claims priority to U.S. Provisional Patent application No. 63/278,049 filed on Nov. 10, 2021, which is hereby incorporated by reference.

### FIELD

This disclosure relates to a single platen CMP process having multiple polishing steps such as Back-End applications.

### BACKGROUND

The single platen CMP process uses a novel Pad-In-A-Bottle (PIB) technology and PIB type advanced metal (such as Cu or Co) bulk, PIB type metal (such as Cu or Co) soft landing, and PIB type metal (such as Cu or Co) barrier Chemical Mechanical Planarization (CMP) slurries, systems and methods with the single platen for three polishing steps in Back-End applications. A selected single polishing pad (hard or soft) on the platen will complete all three steps of polishings subsequently.

Conventionally, for the back-end CMP applications, metal bulk, metal soft landing, and metal Barrier CMP slurries are used three different polishing steps on three different platens on the CMP polishing tool for the whole polishing process as shown in the upper part of FIG. 1. Typically, three different platens are employed with at least two different types of polishing pads for three CMP slurries.

Thus, conventional three platen CMP processes for back-end CMP processed have several weaknesses, such as (a) three different platens are used in a CMP polisher which make the polishing tool large and complicated, (b) at least two different types of polishing pads are needed for each platen in three platen CMP process, (c) wafer transfer times among three different platens will decrease the device fabrication efficiency.

The cost of ownership and the cost of electronic device fabrications on the expensive polyurethane polishing pads is also an important concern for the semiconductor industry in CMP processes.

In CMP, asperities on a polyurethane (PU) pad are irreversibly deformed due to wafer contact and are also abraded by composition particles. As such, the pad surface must be continuously renewed with a diamond disc to ensure process stability. Because diamond disk has to cut the pad surface to eliminate old asperities and create new ones, they also gradually thin the pad, forcing its replacement.

The role of pad asperities is played by high-quality micron-size polyurethane (PU) beads having sizes that are comparable to the sizes of pores and asperities in commercial polishing pads. PIB type CMP slurries contain PU beads.

In the newly invented single platen CMP process (as shown in the lower part of FIG. 1) for back-end CMP applications, a selected first PIB type Cu bulk CMP slurry is used first to remove the desirable thickness of the overburden of the Cu capping layer film, after the step 1, a selected second PIB type Cu soft landing CMP slurry will be used in step 2 to remove the left Cu capping layer to stop on barrier and dielectric films to afford low Cu line dishing, in step 3, a selected third PIB type Cu Barrier is used to remove barrier, dielectric and Cu films with desirable polishing selectivity among different films to be polished to achieve Cu dishing and erosion corrections to obtain further lower Cu dishing and erosion which enhance the electronic device fabrication yield.

### BRIEF SUMMARY

The needs are satisfied by using the disclosed single platen CMP process therein the single platen is used with a single selected polishing pad for all three different PIB type CMP slurries: PIB type Cu bulk, PIB type Cu soft landing and PIB type Cu Barrier CMP slurries used in the back-end CMP processes.

The invented single platen CMP process for back-end CMP applications will reduce the CMP processing times and increase throughput of semiconductor device fabrications.

In one aspect, a PIB type Cu bulk CMP polishing composition is provided in the first step of polishing in a single platen CMP process. The PIB type Cu bulk CMP polishing composition comprises:
abrasives,
micron-size polyurethane (PU) beads having a size ranging from 2 to 100 μm, 10 to 80 μm, 20 to 70 μm, or 30 to 50 μm;
silicone-containing dispersing agent;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

In another aspect, a PIB type Cu soft landing CMP polishing composition is provided in the second step of the polishing in a single platen CMP process. The PIB type Cu soft landing CMP polishing composition comprises:
abrasives,
micron-size polyurethane (PU) beads having a size ranging from 2 to 100 μm, 10 to 80 μm, 20 to 70 μm, or 30 to 50 μm;
silicone-containing dispersing agent;
Cu dishing reducing additive;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

In third aspect, a PIB type Cu barrier CMP polishing composition is provided in the third step of polishing in a single platen CMP process. The PIB type cu barrier CMP polishing composition comprises:
abrasives,
micron-size polyurethane (PU) beads having a size ranging from 2 to 100 μm, 10 to 80 μm, 20 to 70 μm, or 30 to 50 μm;
silicone-containing dispersing agent;
a barrier or dielectric film removal rate boosting additive;
liquid carrier such as water;
and optionally,
Cu dishing reducing additive;
corrosion inhibitor,
pH adjuster;
an oxidizer added at the point of use; and
the pH of the composition can be acidic or alkaline. For acidic pH, pH is from 2.0 to 6.5; for alkaline pH PIB type CMP polishing composition, pH range is from 8 to 11.

In another aspect, a single platen CMP polishing method is provided. The single platen CMP polishing method comprises the steps of:
providing the single platen having a single cost effective polishing pad;
providing the semiconductor patterned wafer having at least one film consisting of copper, barrier, THROUGH-SILICON VIA (TSV) copper Low-k, ultra Low-k and/or other dielectric films;
providing the PIB type Cu bulk CMP polishing composition as stated above polishing the copper film to a controlled thickness, wherein at least a portion of the copper film is in contact with both the polishing pad and the PIB type Cu bulk CMP polishing composition;
providing the PIB type Cu soft landing CMP polishing composition as stated above;
polishing copper film left from the last polishing and stopping on barrier films, wherein at least a portion of the copper film left from the last polishing is in contact with both the polishing pad and the PIB type Cu soft landing CMP polishing composition;
providing the PIB type Cu barrier CMP polishing composition as stated above;
polishing at least one film selected from the group consisting of the barrier, THROUGH-SILICON VIA (TSV) copper film, Low-k, ultra Low-k and/or other dielectric films, and wherein at least a portion of the at least one film is in contact with both polishing pad and the PIB type Cu barrier CMP polishing composition.

In another aspect, a single platen CMP polishing system is provided. The single platen CMP polishing system comprises:
providing the single platen having a single cost effective polishing pad;
providing the semiconductor patterned wafer having at least copper, barrier, THROUGH-SILICON VIA (TSV) copper, Low-k, ultra Low-k and/or other dielectric films;
providing the PIB type Cu bulk CMP polishing composition as stated above to polish the copper film to a controlled thickness, wherein at least a portion of the copper film is in contact with both the polishing pad and the PIB type Cu bulk CMP polishing composition;
providing the PIB type Cu soft landing CMP polishing composition as stated above to polish copper film left from the last polishing and stop on barrier films, wherein at least a portion of the copper film left from the last polishing is in contact with both the polishing pad and the PIB type Cu soft landing CMP polishing composition;
providing the PIB type Cu barrier CMP polishing composition as stated above to polish at least one film selected from the group consisting of the barrier, THROUGH-SILICON VIA (TSV) copper, Low-k, ultra Low-k and/or other dielectric films, wherein at least a portion of the at least one film is in contact with both polishing pad and the PIB type Cu barrier CMP polishing composition.

The abrasive particles include, but are not limited to, colloidal silica or high purity colloidal silica; the colloidal silica particles doped by other metal oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic metal oxide particles, such as alumina, titania, zirconia, ceria etc.; nano-sized diamond particles, nano-sized silicon nitride particles; mono-modal, bi-modal, multi-modal colloidal abrasive particles; organic polymer-based soft abrasives, surface-coated or modified abrasives, or other composite particles, and mixtures thereof.

The silicone-containing dispersing agent includes, but is not limited to, silicone polyethers containing both a water-insoluble silicone backbone and a number of water-soluble polyether pendant groups; such as the repeating units of ethylene oxide (EO) and propylene oxide (PO) (EO-PO) functional groups to provide surface wetting properties.

The corrosion inhibitors include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The chelating agents (or chelators) include, but are not limited to, amino acids, amino acid derivatives, organic amines.

The amino acids and amino acid derivatives include, but not limited to, glycine, D-alanine, L-alanine, DL-alanine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof.

The organic amines include, but not limited to, 2,2-dimethyl-1,3-propanediamine and 2,2-dimethyl-1,4-butanediamine, ethylenediamine, 1,3-diaminepropane, 1,4-diaminebutane, etc.

The organic diamine compounds with two primary amine moieties can be described as the binary chelating agents.

The biocide includes but is not limited to Kathon™, Kathon™ CG/ICP II, from Dow Chemical Co. They have active ingredients of 5-chloro-2-methyl-4-isothiazolin-3-one and 2-methyl-4-isothiazolin-3-one.

The Cu dishing reducing agent includes but is not limited to non-ionic organic surfactants, such as acetylene ethoxylate type of surfactants Dynol607™, Dynol604™ or Polyglycol ether structured Tergitol™ type of non-ionic surfactants, such as Tergitol™ Min Form 1x, Tergitol™ L-62, Tergitol™ L-64, or anionic surfactants, such as organic alkyl sulfonate, organic alkyl phosphate or organic carboxylate. The examples for anionic surfactants are dodecyl sulfonate ammonium or potassium salt, octyl phosphate ammonium or potassium salt, and octyl carboxylate ammonium or potassium salt.

The barrier or dielectric film removal rate boosting additives include, but not limited to, the various salts of silicate, such as ammonium silicate, sodium silicate, potassium silicate or tetraalkyl silicate.

The oxidizing agent includes, but is not limited to, periodic acid, hydrogen peroxide, potassium iodate, potassium permanganate, ammonium persulfate, ammonium molybdate, ferric nitrate, nitric acid, potassium nitrate, and mixtures thereof.

The organic quaternary ammonium salt as Cu removal rate boosting agent and defect reducing agent, includes, but is not limited to, choline salts with different counter ions, such as choline bicarbonate, choline hydroxide, choline dihydrogen citrate salt, choline ethanolamine, choline bitartrate, etc.

The pH adjusting agents include, but are not limited to, the following: nitric acid, hydrochloric acid, sulfuric acid, phosphoric acid, other inorganic or organic acids, and mixtures thereof. pH adjusting agents also include the basic pH adjusting agents, such as sodium hydride, potassium hydroxide, ammonium hydroxide, tetraalkyl ammonium hydroxide, organic amines, and other chemical reagents that are able to be used to adjust pH towards the more alkaline direction.

### BRIEF DESCRIPTION OF SEVERAL VIEWS OF THE DRAWINGS

FIG. 1. A conventional three platens CMP process is compared to a single platen CMP process of the instant disclosure.

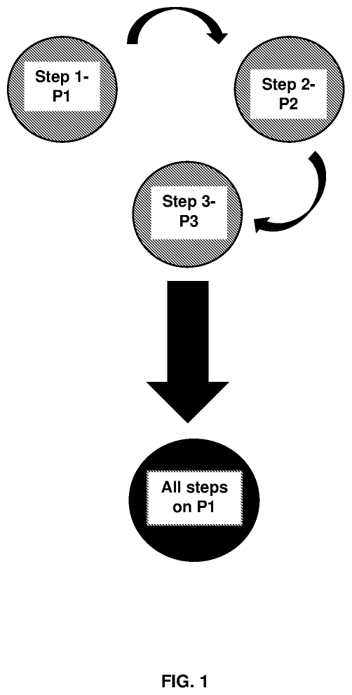

### DETAILED DESCRIPTION

The current disclosure teaches a single platen CMP polishing with a single same polishing pad using PIB type metal bulk, PIB type metal soft landing, and PIB type metal Barrier CMP slurries for back-end CMP applications, such as three step Cu CMP processes.

The current application discloses a new technology where the role of pad asperities is played by high-quality micron-size polyurethane (PU) beads. The size of the PU beads is comparable to the sizes of pores and asperities in commercial polishing pads.

The beads are suspended in a Cu CMP polishing composition having abrasive particles, such as a calcined ceria, colloidal silica, or composite particles with the assistance of a wetting agent (or a surfactant) as the dispersing agent to disperse polyurethane beads in aqueous compositions.

The beads come into contact with the wafer surface by a means described below to promote polishing in much the same way as conventional asperities.

By selecting both the size of the beads, and their concentration in the composition, much better control of the height, curvature, and area density of the “summits” that come in contact with the wafer are achieved, substantially reducing the process variability associated with conventional asperity contact.

Use of beads still requires a second surface, or counter-face, for polishing to occur, which in our case continues to be a conventional polyurethane-based pad, but one that requires minimal conditioning as it is no longer the primary surface where polishing takes place. Alternatively, one can use an inexpensive and partially conditioned pad as the counter-face.

A polisher typically use three platens with two to three pads and using three different CMP polishing compositions for back-end CMP applications. In this disclosure, a single platen process using the same polishing pad and three different CMP slurries will be used to replace three platen CMP processes for back-end CMP applications. The single platen process provides significant cost reductions in semiconductor device fabrication processes and increase the throughout in semiconductor device fabrication efficiency.

Since it can take several hours to remove a used pad, install, and qualify a new one, the engineering and product loss due to tool downtime and consumables used to qualify the new pad are also significant. Using single platen process with the same polishing pad, such pad replacement times can be significantly reduced while comparing three platens process using two to three different polishing pads.

As for a polishing pad, only about two-thirds of a pad thickness is used before the pad has to be stripped and discarded. For conditioner, only a few hundred diamonds out of tens of thousands control the product lifetime, after which the conditioner must be discarded. Furthermore, recycle or reuse options are not available for pads and conditioners. Our work addresses the above EHS issues and offers a novel solution to the current standard CMP processes by eliminating the use of lots of pads and diamond disc conditioners.

Polyurethane beads used in the disclosed 3 different types of CMP polishing compositions for single platen back-end CMP applications have a size ranging from 2 to 100 μm, 10 to 80 μm, 20 to 70 μm, or 30 to 50 μm.

Several specific aspects of the present invention are outlined below.

In one aspect, a PIB type Cu bulk CMP polishing composition is provided in the first step of polishing in a single platen CMP process. The PIB type Cu bulk CMP polishing composition comprises:
abrasives,
micron-size polyurethane (PU) beads having a size ranging from 2 to 100 am, 10 to 80 μm, 20 to 70 μm, or 30 to 50 μm;
silicone-containing dispersing agent;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

In another aspect, a PIB type Cu soft landing CMP polishing composition is provided in the second step of the polishing in a single platen CMP process. The PIB type Cu soft landing CMP polishing composition comprises:
abrasives,
micron-size polyurethane (PU) beads having a size ranging from 2 to 100 μm, 10 to 80 μm, 20 to 70 μm, or 30 to 50 μm;
silicone-containing dispersing agent;
Cu dishing reducing additive;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

In third aspect, a PIB type Cu barrier CMP polishing composition is provided in the third step of polishing in a single platen CMP process. The PIB type Cu barrier CMP polishing composition comprises:
abrasives,
micron-size polyurethane (PU) beads having a size ranging from 2 to 100 am, 10 to 80 μm, 20 to 70 μm, or 30 to 50 μm;
silicone-containing dispersing agent;
a barrier or dielectric film removal rate boosting additive;
liquid carrier such as water;
and optionally,
Cu dishing reducing additive;
corrosion inhibitor,
pH adjuster;
an oxidizer added at the point of use; and
the pH of the composition can be acidic or alkaline. For acidic pH, pH is from 2.0 to 6.5; for alkaline pH PIB type CMP polishing composition, pH range is from 8 to 11.

In another aspect, a single platen CMP polishing method is provided. The single platen CMP polishing method comprises the steps of:
providing the single platen having a single cost effective polishing pad;
providing the semiconductor patterned wafer having at least one file selected from the group consisting of copper, barrier, THROUGH-SILICON VIA (TSV) copper Low-k, ultra Low-k and/or other dielectric films;
providing the PIB type Cu bulk CMP polishing composition as stated above
polishing the copper film to a controlled thickness, wherein at least a portion of the copper film is in contact with both the polishing pad and the PIB type Cu bulk CMP polishing composition;
providing the PIB type Cu soft landing CMP polishing composition as stated above;
polishing copper film left from the last polishing and stopping on barrier films, wherein at least a portion of the copper film left from the last polishing is in contact with both the polishing pad and the PIB type Cu soft landing CMP polishing composition;
providing the PIB type Cu barrier CMP polishing composition as stated above;
polishing at least one film selected from the group consisting of the barrier, THROUGH-SILICON VIA (TSV) copper film, Low-k, ultra Low-k and/or other dielectric films, and wherein at least a portion of the at least one film is in contact with both polishing pad and the PIB type Cu barrier CMP polishing composition.

In yet another aspect, a single platen CMP polishing system is provided. The single platen CMP polishing system comprises:
providing the single platen having a single cost effective polishing pad;
providing the semiconductor patterned wafer having at least copper, barrier, THROUGH-SILICON VIA (TSV) copper, Low-k, ultra Low-k and/or other dielectric films;
providing the PIB type Cu bulk CMP polishing composition as stated above to polish the copper film to a controlled thickness, wherein at least a portion of the copper film is in contact with both the polishing pad and the PIB type Cu bulk CMP polishing composition;
providing the PIB type Cu soft landing CMP polishing composition as stated above to polish copper film left from the last polishing and stop on barrier films, wherein at least a portion of the copper film left from the last polishing is in contact with both the polishing pad and the PIB type Cu soft landing CMP polishing composition;
providing the PIB type Cu barrier CMP polishing composition as stated above to polish at least one film selected from the group consisting of the barrier, THROUGH-SILICON VIA (TSV) copper, Low-k, ultra Low-k and/or other dielectric films, wherein at least a portion of the at least one film is in contact with both polishing pad and the PIB type Cu barrier CMP polishing composition.

The abrasive particles are nano-sized particles, include, but are not limited to, colloidal silica or high purity colloidal silica; the colloidal silica particles doped by other metal oxide within lattice of the colloidal silica, such as alumina doped silica particles; colloidal aluminum oxide including alpha-, beta-, and gamma-types of aluminum oxides; colloidal and photoactive titanium dioxide, cerium oxide, colloidal cerium oxide, nano-sized inorganic metal oxide particles, such as alumina, titania, zirconia, ceria etc.; nano-sized diamond particles, nano-sized silicon nitride particles; mono-modal, bi-modal, multi-modal colloidal abrasive particles; organic polymer-based soft abrasives, surface-coated or modified abrasives, or other composite particles, and mixtures thereof.

The colloidal silica can be made from silicate salts, the high purity colloidal silica can be made from TEOS or TMOS. The colloidal silica or high purity colloidal silica can have narrow or broad particle size distributions with mono-model or multi-models, various sizes and various shapes including spherical shape, cocoon shape, aggregate shape and other shapes.

The nano-sized particles also can have different shapes, such as spherical, cocoon, aggregate, and others.

The particle size of the abrasives used in the Cu CMP slurries is ranged from 5 nm to 500 nm, 10 nm to 250 nm, or 25 nm to 100 nm.

The Cu CMP polishing compositions comprise 0.0025 wt. % to 25 wt. % abrasives; 0.0025 wt. % to 2.5 wt. %; 0.005 wt. % to 0.5 wt. %.

The CMP polishing compositions comprise silicone-containing dispersing agent to disperse the polyurethane beads in aqueous solutions. The silicone-containing dispersing agent also functions as a surface wetting agent dispersing agent.

The silicone-containing dispersing agent includes, but is not limited to, silicone polyethers containing both a water-insoluble silicone backbone and a number of water-soluble polyether pendant groups; such as the repeating units of EO-PO functional groups to provide surface wetting properties.

Examples of the silicone-containing dispersing agent includes Silsurf® E608, Silsurf® J208-6, Silsurf® A208, Silsurf® CR1115, Silsurf® A204, Silsurf® A004-UP, Silsurf® A008-UP, Silsurf® B608, Silsurf® C208, Silsurf® C410, Silsurf® D208, Silsurf® D208, Silsurf® D208-30, Silsurf® Di-1010, Silsurf® Di-1510, Silsurf® Di-15-I, Silsurf® Di-2012, Silsurf® Di-5018-F, Silsurf® G8-I, Silsurf® J1015-O, Silsurf® J1015-O-AC, Silsurf® J208, Silsurf® J208-6, Siltech® OP-8, Siltech® OP-11, Siltech® OP-12, Siltech® OP-15, Siltech® OP-20; the products from Siltech Corporation; 225 Wicksteed Avenue, Toronto Ontario, Canada M4H 1G5.

The concentration range of the silicone-containing dispersing agent is from 0.01 wt. % to 2.0 wt. %, 0.025 wt. % to 1.0 wt. %, or 0.05 wt. % to 0.5 wt. %.

The CMP slurry contains various sized polyurethane beads.

The concentration range of the polyurethane beads is from 0.01 wt. % to 2.0 wt. %, 0.025 wt. % to 1.0 wt. %, or 0.05 wt. % to 0.5 wt. %.

The organic quaternary ammonium salt as Cu removal rate boosting agent and defect reducing agent, includes but is not limited to choline salt, such as choline bicarbonate salt, or all other salts formed between choline and other anionic counter ions.

The CMP slurry contains 0.005 wt. % to 0.5 wt. %, 0.001 wt. % to 0.25 wt. %; or 0.002 wt. % to 0.1 wt. % of quaternary ammonium salt.

The CMP slurry contains 0.1 wt. % to 18 wt. %; 0.5 wt. % to 15 wt. %; or 1.0 wt. % to 10.0 wt. % of at least one chelator, dual chelators or tris chelators.

The chelating agents (or chelators) include, but are not limited to, amino acids, amino acid derivatives, organic amines.

The amino acids and amino acid derivatives include, but not limited to, glycine, D-alanine, L-alanine, DL-alanine, beta-alanine, valine, leucine, isoleucine, phenylamine, proline, serine, threonine, tyrosine, glutamine, asparagine, glutamic acid, aspartic acid, tryptophan, histidine, arginine, lysine, methionine, cysteine, iminodiacetic acid, and combinations thereof.

The organic amines include, but not limited to, 2,2-dimethyl-1,3-propanediamine and 2,2-dimethyl-1,4-butanediamine, ethylenediamine, 1,3-diaminepropane, 1,4-diaminebutane etc.

The organic diamine compounds with two primary amine moieties can be described as the binary chelating agents.

The corrosion inhibitors can be any known reported corrosion inhibitors.

The corrosion inhibitors for example, include but are not limited to family of hetero aromatic compounds containing nitrogen atom(s) in their aromatic rings, such as 1,2,4-triazole, amitrole (3-amino-1,2,4-triazole), benzotriazole and benzotriazole derivatives, tetrazole and tetrazole derivatives, imidazole and imidazole derivatives, benzimidazole and benzimidazole derivatives, pyrazole and pyrazole derivatives, and tetrazole and tetrazole derivatives.

The CMP slurry contains 0.005 wt. % to 1.0 wt. %; 0.01 wt. % to 0.5 wt. %; or 0.025 wt. % to 0.25 wt. % of corrosion inhibitor.

A biocide having active ingredients for providing more stable shelf time of the Cu chemical mechanical polishing compositions can be used.

The biocide includes but is not limited to Kathon™, Kathon™ CG/ICP II, from Dow Chemical Co. They have active ingredients of 5-chloro-2-methyl-4-isothiazolin-3-one and/or 2-methyl-4-isothiazolin-3-one.

The CMP slurry contains 0.0001 wt. % to 0.05 wt. %; 0.0001 wt. % to 0.025 wt. %; or 0.0001 wt. % to 0.01 wt. % of biocide.

Acidic or basic compounds or pH adjusting agents can be used to allow pH of CMP polishing compositions being adjusted to the optimized pH value,

The pH adjusting agents include, but are not limited to, the following: nitric acid, hydrochloric acid, sulfuric acid, phosphoric acid, other inorganic or organic acids, and mixtures thereof. pH adjusting agents also include the basic pH adjusting agents, such as sodium hydride, potassium hydroxide, ammonium hydroxide, tetraalkyl ammonium hydroxide, organic amines, and other chemical reagents that are able to be used to adjust pH towards the more alkaline direction.

The CMP slurry contains 0 wt. % to 1 wt. %; 0.01 wt. % to 0.5 wt. %; or 0.1 wt. % to 0.25 wt. % of pH adjusting agent.

The Cu dishing reducing agent includes but is not limited to non-ionic organic surfactants, such as acetylene ethoxylate type of surfactants Dynol607™, Dynol604™ or Polyglycol ether structured Tergitol™ type of non-ionic surfactants, such as Tergitol™ Min Form 1x, Tergitol™ L-62, Tergitol™ L-64, or anionic surfactants, such as organic alkyl sulfonate, organic alkyl phosphate or organic carboxylate. The examples for anionic surfactants are dodecyl sulfonate ammonium or potassium salt, octyl phosphate ammonium or potassium salt, and octyl carboxylate ammonium or potassium salt.

The concentrations of the Cu dishing reducing additives is ranged from 0.0005 wt. % to 0.25 wt. %, the preferred concentration rang is from 0.001 wt. % to 0.125 wt. %. The more preferred concentration range is from 0.025 wt. % to 0.10 wt. %.

The barrier or dielectric film removal rate boosting additives include, but not limited to, the various salts of silicate, such as ammonium silicate, sodium silicate, potassium silicate or tetraalkyl silicate.

The CMP slurry contains 0 wt. % to 2 wt. %; 0.1 wt. % to 1.5 wt. %; or 0.25 wt. % to 1 wt. % of barrier or dielectric film removal rate boosting additives.

pH of the PIB type Cu bulk and Cu soft landing polishing compositions is from about 3.0 to about 12.0; preferred pH range is from 5.5 to 7.5; and the most preferred pH range is from 6.0 to 7.5.

pH of the PIB type Cu barrier CMP polishing composition can be acidic or alkaline. For acidic pH, pH is from 2.0 to 6.5; for alkaline pH PIB type CMP polishing composition, pH range is from 8 to 11.

### EXPERIMENTAL SECTION

### Parameters

Å: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: polishing composition flow, ml/min

### Removal Rates (RR):

Cu RR 0.5 psi Measured Copper removal rate at 0.5 psi down pressure of the CMP tool
Cu RR 1.0 psi Measured Copper removal rate at 1.0 psi down pressure of the CMP tool
Cu RR 2.0 psi Measured Copper removal rate at 2.0 psi down pressure of the CMP tool
Cu RR 2.5 psi Measured Copper removal rate at 2.5 psi down pressure of the CMP tool
TEOS RR 0.5 psi Measured TEOS removal rate at 0.5 psi down pressure of the CMP tool
TEOS RR 1.0 psi Measured TEOS removal rate at 1.0 psi down pressure of the CMP tool
TEOS RR 2.0 psi Measured TEOS removal rate at 2.0 psi down pressure of the CMP tool
TaN RR 0.5 psi Measured TaN removal rate at 0.5 psi down pressure of the CMP tool
TaN RR 1.0 psi Measured TaN removal rate at 1.0 psi down pressure of the CMP tool
TaN RR 2.0 psi Measured TaN removal rate at 2.0 psi down pressure of the CMP tool
BD RR 0.5 psi Measured BD removal rate at 0.5 psi down pressure of the CMP tool
BD RR 1.0 psi Measured BD removal rate at 1.0 psi down pressure of the CMP tool
BD RR 2.0 psi Measured BD removal rate at 2.0 psi down pressure of the CMP tool
TiN RR 1.0 psi Measured TiN removal rate at 1.0 psi down pressure of the CMP tool
TiN RR 2.0 psi Measured TiN removal rate at 2.0 psi down pressure of the CMP tool

### General Experimental Procedure

All percentages in the compositions are weight percentages unless otherwise indicated.

In the examples presented below, CMP experiments were run using the procedures and experimental conditions given below. The CMP tool that was used in the examples is a 300 mm APD-800© polisher, manufactured by Fujikoshi Machinery Corporation (Nagano Japan). Pads were broken-in by polishing twenty-five dummy oxide (deposited by plasma enhanced CVD from a TEOS precursor, PETEOS) wafers. In order to qualify the tool settings and the pad break-in, two PETEOS monitors were polished with Syton® OX-K colloidal silica, supplied by Planarization Platform of Versum Materials, Inc. at baseline conditions. Polishing experiments were conducted using blanket Cu, TEOS, TaN, TiN, and BD wafers. These blanket wafers were purchased from Silicon Valley Microelectronics, 1150 Campbell Ave, CA, 95126.

Polishing pad, Hard polishing pad, IC1010, was supplied by DuPont in USA. Soft Fujibo pad, supplied by Fujibo Corporation in Japan. The hard polishing pad is made of a rigid, micro-porous polyurethane material. The hard polishing pad may be IC 1010 with a compressibility of about 0.5%-4.0% and a hardness of about 52-62 (Shore D). Both hard and soft polishing pads were used respectively on the single platen for the Cu bulk, Cu soft landing and Barrier blanket wafer polishing studies.

### Working Example

### Example 1—Using Hard IC1010 Pad on a Single Platen Process

On the single platen processing, PIB Cu bulk CMP polishing composition comprised of 5.20 wt. % glycine, 2.40 wt. % alanine, 0.016 wt. % Amitrole, 0.0231 wt. % choline bicarbonate, 0.0016 wt. % Neolone M10 biocide, 0.2705 wt. % high purity colloidal silica particles as abrasive, 0.050 wt. % Silsurf E608 as dispersing agent and 0.10 wt. % 35 micron sized polyurethane beads.

Silsurf E608 containing EO-PO wetting functional groups was used as the silicone-containing dispersing agent.

On the single platen processing, PIB Cu soft landing CMP polishing composition comprised of EMD Electronics Cu soft landing slurry, Cu3086, with added 0.050 wt. % Silsurf E608 as dispersing agent and 0.10 wt. % 35 micron sized polyurethane beads.

On the single platen processing, PIB Barrier CMP polishing composition comprised of EMD Electronics, BAR6610R slurry, with added 0.050 wt. % Silsurf E608 as dispersing agent and 0.25 wt. % 35 micron sized polyurethane beads.

2.5 wt. % H₂O₂ was added into the PIB Cu bulk CMP composition at the point of use for the polishing testing on a single platen.

1.0 wt. % H₂O₂ was added into the PIB Cu soft landing CMP composition at the point of use for the polishing testing on a single platen.

1.0 wt. % H₂O₂ was added into the PIB BAR6610R barrier CMP composition at the point of use for the polishing testing on a single platen.

The polishing testing were conducted hard IC1010 pad on a single platen process with different applied down force and sliding velocities.

The polishing results are listed in Table 1 to Table 3 which used hard IC1010 polishing pad on a single platen process.

TABLE 1
PIB-Type Cu Bulk CMP Slurry Polishing Results on IC1010 Pad

| | | Sliding | | |
|---|---|---|---|---|
| Wafer | Down Force | Velocity | Mean | Film RR |
| Type | (PSI) | (m/s) | COF | (Å/min.) |
| Cu | 1 | 1 | 0.372 | 8400 |
| | 1 | 1.5 | 0.372 | 9674 |
| | 2 | 1 | 0.381 | 10790 |
| | 2 | 1.5 | 0.376 | 13832 |
| | 2.5 | 1 | 0.374 | 12980 |
| | 2.5 | 1.5 | 0.368 | 17780 |
| TEOS | 1 | 1 | 0.463 | 0 |
| | 1 | 1.5 | 0.511 | 0 |
| | 2 | 1 | 0.531 | 3 |
| | 2 | 1.5 | 0.568 | 3 |
| TaN | 1 | 1 | 0.463 | 11 |
| | 1 | 1.5 | 0.498 | 9 |
| | 2 | 1 | 0.530 | 6 |
| | 2 | 1.5 | 0.568 | 11 |

As the polishing results are listed in Table 1, the highest Cu removal rate is achieved with Cu PIB bulk CMP slurry at 2.5 psi down force and 1.5 m/s sliding velocity on the single platen process using hard IC1010 pad. The PIB-type of Cu bulk slurry on a single platen process provides high Cu:TEOS polishing selectivity at >4500:1 and Cu:TaN polishing selectivity at >1200:1 at 2.0 psi down force and 1.5 m/s sliding velocity.

After completing PIB-type Cu bulk slurry CMP polishing process on a single platen, Cu soft landing CMP slurry is used subsequently for the step two CMP process on the single platen process. The results are listed in Table 2.

TABLE 2
PIB-Type Cu Soft Landing CMP Slurry
Polishing Results on IC1010 Pad

| | | Sliding | | |
|---|---|---|---|---|
| Wafer | Down Force | Velocity | Mean | Film RR |
| Type | (PSI) | (m/s) | COF | (Å/min.) |
| Cu | 0.5 | 0.5 | 0.392 | 463 |
| | 0.5 | 1 | 0.564 | 1089 |
| | 1 | 0.5 | 0.411 | 880 |
| | 1 | 1 | 0.552 | 1847 |
| TEOS | 0.5 | 0.5 | 0.411 | 1 |
| | 0.5 | 1 | 0.281 | 1 |
| | 1 | 0.5 | 0.365 | 1 |
| | 1 | 1 | 0.274 | 1 |
| TaN | 0.5 | 0.5 | 0.292 | 23 |
| | 0.5 | 1 | 0.266 | 23 |
| | 1 | 0.5 | 0.305 | 27 |
| | 1 | 1 | 0.286 | 9 |
| BD | 0.5 | 0.5 | 0.448 | 0 |
| | 0.5 | 1 | 0.456 | 0 |
| | 1 | 0.5 | 0.460 | 0 |
| | 1 | 1 | 0.476 | 0 |

As the polishing results are listed in Table 2, the highest Cu removal rate is achieved with Cu PIB bulk CMP slurry at 1.0 psi down force and 1.0 m/s sliding velocity on the single platen process. The PIB-type of Cu soft landing slurry on a single platen process provides high Cu:TEOS polishing selectivity, high Cu:BD polishing selectivity and good Cu:TaN polishing selectivity. PIB-type Cu soft landing CMP slurry being used on the single platen process provides almost fully stop CMP polishing performances on polishing dielectric films, TEOS and BD while using a hard IC1010 polishing pad.

After completing PIB-type Cu soft landing slurry CMP polishing process on a single platen, a PIB-type barrier CMP slurry is used subsequently for the step three CMP process on the single platen process. The results are listed in Table 3.

TABLE 3
PIB-Type Barrier CMP Slurry Polishing Results on IC1010 Pad

| | | Sliding | | |
|---|---|---|---|---|
| Wafer | Down Force | Velocity | Mean | Film RR |
| Type | (PSI) | (m/s) | COF | (Å/min.) |
| Cu | 1 | 0.5 | 0.465 | 0 |
| | 1 | 1 | 0.422 | 0 |
| | 2 | 0.5 | 0.434 | 0 |
| | 2 | 1 | 0.414 | 0 |
| TEOS | 1 | 0.5 | 0.507 | 80 |
| | 1 | 1 | 0.437 | 146 |
| | 2 | 0.5 | 0.622 | 140 |
| | 2 | 1 | 0.412 | 290 |
| TaN | 1 | 0.5 | 0.583 | 49 |
| | 1 | 1 | 0.643 | 76 |
| | 2 | 0.5 | 0.575 | 122 |
| | 2 | 1 | 0.643 | 199 |
| BD | 1 | 0.5 | 0.536 | 0 |
| | 1 | 1 | 0.561 | 0 |
| | 2 | 0.5 | 0.509 | 0 |
| | 2 | 1 | 0.565 | 0 |
| TiN | 1 | 0.5 | 0.497 | 820 |
| | 1 | 1 | 0.513 | 1330 |
| | 2 | 0.5 | 0.533 | 1366 |
| | 2 | 1 | 0.564 | 2174 |

As the polishing results are listed in Table 3, higher TiN removal rate are achieved at four different applied down force and sliding velocity combination conditions. The PIB barrier slurry also provides the fully stop CMP polishing performances on polishing Cu and BD films at different applied down force and sliding velocity combination conditions on the single platen process and with hard IC1010 polishing pad. The PIB-type of barrier CMP slurry on a single platen process provides the reasonable TEOS and TaN removal rates while using a hard IC1010 polishing pad.

### Example 2—Using Soft Fujibo Pad on a Single Platen Process

On the single platen processing, PIB Cu bulk CMP polishing composition comprised of 5.20 wt. % glycine, 2.40 wt. % alanine, 0.016 wt. % Amitrole, 0.0231 wt. % choline bicarbonate, 0.0016 wt. % Neolone M10 biocide, 0.2705 wt. % high purity colloidal silica particles as abrasive, 0.050 wt. % Silsurf E608 as dispersing agent and 0.10 wt. % 35 micron sized polyurethane beads.

Silsurf E608 containing EO-PO wetting functional groups was used as the silicone-containing dispersing agent.

On the single platen processing, PIB Cu soft landing CMP polishing composition comprised of EMD Electronics Cu soft landing slurry, Cu3086, with added 0.050 wt. % Silsurf E608 as dispersing agent and 0.10 wt. % 35 micron sized polyurethane beads.

On the single platen processing, PIB Barrier CMP polishing composition comprised of EMD Electronics, BAR6610R slurry, with added 0.050 wt. % Silsurf E608 as dispersing agent and 0.25 wt. % 35 micron sized polyurethane beads.

2.5 wt. % H₂O₂ was added into the PIB Cu bulk CMP composition at the point of use for the polishing testing on a single platen.

1.0 wt. % H₂O₂ was added into the PIB Cu soft landing CMP composition at the point of use for the polishing testing on a single platen.

1.0 wt. % H₂O₂ was added into the PIB BAR6610R barrier CMP composition at the point of use for the polishing testing on a single platen.

The polishing testing were conducted using soft Fujibo pad on a single platen process with different applied down force and sliding velocities.

The polishing results are listed in Table 4 to Table 6 which used soft Fujibo polishing pad on a single platen process.

TABLE 4
PIB-Type Cu Bulk CMP Slurry Polishing Results on Fujibo Pad

| | | Sliding | | |
|---|---|---|---|---|
| Wafer | Down Force | Velocity | Mean | Film RR |
| Type | (PSI) | (m/s) | COF | (Å/min.) |
| Cu | 1 | 1 | 0.507 | 8656 |
| | 1 | 1.5 | 0.546 | 9564 |
| | 2 | 1 | 0.499 | 12366 |
| | 2 | 1.5 | 0.502 | 15954 |
| | 2.5 | 1 | 0.495 | 14440 |
| | 2.5 | 1.5 | 0.483 | 18700 |
| TEOS | 1 | 1 | 0.702 | 0 |
| | 1 | 1.5 | 0.693 | 1 |
| | 2 | 1 | 0.636 | 0 |
| | 2 | 1.5 | 0.572 | 2 |
| TaN | 1 | 1 | 0.692 | 6 |
| | 1 | 1.5 | 0.743 | 5 |
| | 2 | 1 | 0.654 | 4 |
| | 2 | 1.5 | 0.599 | 11 |

As the polishing results are listed in Table 4, the highest Cu removal rate is achieved with Cu PIB bulk CMP slurry at 2.5 psi down force and 1.5 m/s sliding velocity on the single platen process using soft Fujibo pad. The Cu removal rate obtained using soft Fujibo pad is even higher than the Cu removal rate obtained using hard IC1010 pad at the same down force and sliding velocity. The PIB-type of Cu bulk slurry on a single platen process provides very high Cu:TEOS polishing selectivity at >7900:1 and Cu:TaN polishing selectivity at about 1450:1 at 2.0 psi down force and 1.5 m/s sliding velocity using soft Fujibo pad. Thus, using the same PIB-type Cu bulk slurry at the same applied down force and sliding velocity, soft Fujibo pad provides higher Cu:TEOS and Cu:TaN selectivities than the selectivities obtained using hard IC1010 pad.

After completing PIB-type Cu bulk slurry CMP polishing process on a single platen, Cu soft landing CMP slurry is used subsequently for the step two CMP process on the single platen process using soft Fujibo pad. The results are listed in Table 5.

TABLE 5
PIB-Type Cu Soft Landing CMP Slurry
Polishing Results on Fujibo Pad

| | | Sliding | | |
|---|---|---|---|---|
| Wafer | Down Force | Velocity | Mean | Film RR |
| Type | (PSI) | (m/s) | COF | (Å/min.) |
| Cu | 0.5 | 0.5 | 0.484 | 881 |
| | 0.5 | 1 | 0.466 | 1074 |
| | 1 | 0.5 | 0.479 | 1278 |
| | 1 | 1 | 0.427 | 1512 |
| TEOS | 0.5 | 0.5 | 0.649 | 0 |
| | 0.5 | 1 | 0.511 | 0 |
| | 1 | 0.5 | 0.549 | 0 |
| | 1 | 1 | 0.474 | 0 |
| TaN | 0.5 | 0.5 | 0.544 | 0 |
| | 0.5 | 1 | 0.507 | 0 |
| | 1 | 0.5 | 0.537 | 0 |
| | 1 | 1 | 0.490 | 0 |
| BD | 0.5 | 0.5 | 0.607 | 0 |
| | 0.5 | 1 | 0.557 | 0 |
| | 1 | 0.5 | 0.659 | 0 |
| | 1 | 1 | 0.609 | 0 |

As the polishing results are listed in Table 5, the highest Cu removal rate is achieved with Cu PIB bulk CMP slurry at 1.0 psi down force and 1.0 m/s sliding velocity on the single platen process using soft Fujibo pad. The PIB-type of Cu soft landing slurry on a single platen process provides very high Cu:TEOS polishing selectivity, very high Cu:BD polishing selectivity and very high Cu:TaN polishing selectivity. PIB-type Cu soft landing CMP slurry being used on the single platen process provides fully stop CMP polishing performances on polishing dielectric films, TEOS and BD while using a soft Fujibo polishing pad.

After completing PIB-type Cu soft landing slurry CMP polishing process on a single platen using soft Fujibo pad, a PIB-type barrier CMP slurry is used subsequently for the step three CMP process on the single platen process. The results are listed in Table 6.

TABLE 6
PIB-Type Barrier CMP Slurry Polishing Results on Fujibo Pad

| | | Sliding | | |
|---|---|---|---|---|
| Wafer | Down Force | Velocity | Mean | Film RR |
| Type | (PSI) | (m/s) | COF | (Å/min.) |
| Cu | 1 | 0.5 | 0.562 | 46 |
| | 1 | 1 | 0.614 | 37 |
| | 2 | 0.5 | 0.580 | 40 |
| | 2 | 1 | 0.639 | 71 |
| TEOS | 1 | 0.5 | 0.443 | 211 |
| | 1 | 1 | 0.454 | 358 |
| | 2 | 0.5 | 0.454 | 398 |
| | 2 | 1 | 0.450 | 679 |
| TaN | 1 | 0.5 | 0.573 | 190 |
| | 1 | 1 | 0.570 | 373 |
| | 2 | 0.5 | 0.598 | 353 |
| | 2 | 1 | 0.585 | 721 |
| BD | 1 | 0.5 | 0.648 | 8 |
| | 1 | 1 | 0.709 | 114 |
| | 2 | 0.5 | 0.648 | 30 |
| | 2 | 1 | 0.658 | 105 |
| TiN | 1 | 0.5 | 0.622 | 708 |
| | 1 | 1 | 0.650 | 1428 |
| | 2 | 0.5 | 0.628 | 1320 |
| | 2 | 1 | 0.630 | 2774 |

As the polishing results are listed in Table 5, higher TiN removal rate are achieved at four different applied down force and sliding velocity combination conditions. The PIB barrier slurry also provides the desirable Cu removal rates, good TEOS, TaN and BD film removal rates.

Above listed polishing results in Table 1 to Table 6 either using hard IC1010 pad or soft Fujibo pad at different applied down force and sliding velocity conditions, there different CMP polishing compositions, PIB Cu Bulk, PIB Cu soft landing, and PIB Barrier slurries can be successfully used on a single platen CMP process for back-end CMP applications.

The embodiments of this invention listed above are exemplary of numerous embodiments that may be made of this invention. It is contemplated that numerous other configurations of the process may be used, and the materials used in the process may be elected from numerous materials other than those specifically disclosed.

We claim:

1. A single platen Chemical Mechanical Planarization (CMP) polishing method for back-end copper process comprises steps of:
providing the single platen having a single polishing pad;
providing the semiconductor patterned wafer having at least one film consisting of copper, barrier, THROUGH-SILICON VIA (TSV) copper Low-k, ultra Low-k and/or other dielectric films;
providing PIB type Cu bulk CMP polishing composition;
polishing the copper film to a controlled thickness, wherein at least a portion of the copper film is in contact with both the single polishing pad and the PIB type Cu bulk CMP polishing composition;
providing PIB type Cu soft landing CMP polishing composition;
polishing copper film left from the last polishing and stopping on barrier films, wherein at least a portion of the copper film left from the last polishing is in contact with both the single polishing pad and the PIB type Cu soft landing CMP polishing composition;
providing PIB type Cu barrier CMP polishing composition;
polishing at least one film selected from the group consisting of the barrier, THROUGH-SILICON VIA (TSV) copper film, Low-k, ultra Low-k and/or other dielectric films, and wherein at least a portion of the at least one film is in contact with both the single polishing pad and the PIB type Cu barrier CMP polishing composition.

2. The single platen Chemical Mechanical Planarization (CMP) polishing method of claim 1, wherein the PIB type Cu bulk CMP polishing composition comprises
abrasives,
micron-size polyurethane (PU) beads having a size ranging from 2 to 100 μm, 10 to 80 μm, 20 to 70 μm, or 30 to 50 μm;
silicone-containing dispersing agent;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

3. The single platen Chemical Mechanical Planarization (CMP) polishing method of claim 1, wherein the single polishing pad comprises micro-porous polyurethane material.

4. The single platen Chemical Mechanical Planarization (CMP) polishing method of claim 1, wherein the PIB type Cu soft landing CMP polishing composition comprises:
abrasives,
micron-size polyurethane (PU) beads having a size ranging from 2 to 100 μm, 10 to 80 μm, 20 to 70 μm, or 30 to 50 μm;
silicone-containing dispersing agent;
Cu dishing reducing additive;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

5. The single platen Chemical Mechanical Planarization (CMP) polishing method of claim 1, wherein the PIB type Cu barrier CMP polishing composition comprises:
abrasives,
micron-size polyurethane (PU) beads having a size ranging from 2 to 100 μm, 10 to 80 μm, 20 to 70 μm, or 30 to 50 μm;
silicone-containing dispersing agent;
a barrier or dielectric film removal rate boosting additive;
liquid carrier such as water;
and optionally,
Cu dishing reducing additive;
corrosion inhibitor,
pH adjuster;
an oxidizer added at the point of use; and
the pH of the composition is from 2.0 to 6.5 for acidic pH, or 8 to 11 for alkaline pH.

6. The single platen Chemical Mechanical Planarization (CMP) polishing method of claim 1, wherein the micron-size polyurethane (PU) beads having a size ranging from 30 to 50 μm.

7. A single platen Chemical Mechanical Planarization (CMP) polishing system for back-end copper process comprises:
providing the single platen having a single cost effective polishing pad;
providing the semiconductor patterned wafer having at least one film consisting of copper, barrier, THROUGH-SILICON VIA (TSV) copper Low-k, ultra Low-k and/or other dielectric films;
providing PIB type Cu bulk CMP polishing composition to polish the copper film to a controlled thickness, wherein at least a portion of the copper film is in contact with both the polishing pad and the PIB type Cu bulk CMP polishing composition;
providing PIB type Cu soft landing CMP polishing composition to polish copper film left from the last polishing and stopping on barrier films, wherein at least a portion of the copper film left from the last polishing is in contact with both the polishing pad and the PIB type Cu soft landing CMP polishing composition;
providing PIB type Cu barrier CMP polishing composition to polish at least one film selected from the group consisting of the barrier, THROUGH-SILICON VIA (TSV) copper film, Low-k, ultra Low-k and/or other dielectric films, and wherein at least a portion of the at least one film is in contact with both polishing pad and the PIB type Cu barrier CMP polishing composition.

8. The single platen Chemical Mechanical Planarization (CMP) polishing system of claim 7, wherein the PIB type Cu bulk CMP polishing composition comprises
abrasives,
micron-size polyurethane (PU) beads having a size ranging from 2 to 100 μm, 10 to 80 μm, 20 to 70 μm, or 30 to 50 μm;
silicone-containing dispersing agent;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

9. The single platen Chemical Mechanical Planarization (CMP) polishing system of claim 7, wherein the single polishing pad comprises micro-porous polyurethane material.

10. The single platen Chemical Mechanical Planarization (CMP) polishing system of claim 7, wherein the PIB type Cu soft landing CMP polishing composition comprises:
abrasives,
micron-size polyurethane (PU) beads having a size ranging from 2 to 100 μm, 10 to 80 μm, 20 to 70 μm, or 30 to 50 μm;
silicone-containing dispersing agent;
Cu dishing reducing additive;
liquid carrier such as water;
and optionally,
a chelating agent or dual chelating agents or tris chelating agents,
corrosion inhibitor,
organic quaternary ammonium salt,
a biocide;
pH adjuster;
an oxidizer added at the point of use; and
the pH of the composition is from 3.0 to 12.0; 5.5 to 7.5; or 6.0 to 7.5.

11. The single platen Chemical Mechanical Planarization (CMP) polishing system of claim 7, wherein the PIB type Cu barrier CMP polishing composition comprises:
abrasives,
micron-size polyurethane (PU) beads having a size ranging from 2 to 100 am, 10 to 80 μm, 20 to 70 μm, or 30 to 50 μm;
silicone-containing dispersing agent;
a barrier or dielectric film removal rate boosting additive;
liquid carrier such as water;
and optionally,
Cu dishing reducing additive;
corrosion inhibitor,
pH adjuster;
an oxidizer added at the point of use; and
the pH of the composition is from 2.0 to 6.5 for acidic pH, or 8 to 11 for alkaline pH.

12. The single platen Chemical Mechanical Planarization (CMP) polishing system of claim 7, wherein the single polishing pad comprises micro-porous polyurethane material.

13. The single platen Chemical Mechanical Planarization (CMP) polishing system of claim 7, wherein the micron-size polyurethane (PU) beads having a size ranging from 30 to 50 μm.
